(19) United States
(12) Patent Application Publication
(10) Pub. No.: US 2024/0324388 A1
(43) Pub. Date: Sep. 26, 2024

(54) DISPLAY APPARATUS AND METHOD OF MANUFACTURING THE SAME

(71) Applicant: Samsung Display Co., Ltd., Yongin-si (KR)

(72) Inventors: Donggyu Baeck, Yongin-si (KR); Minseok Kim, Yongin-si (KR)

(21) Appl. No.: 18/604,311

(22) Filed: Mar. 13, 2024

(30) Foreign Application Priority Data
Mar. 24, 2023 (KR) 10-2023-0039174
May 9, 2023 (KR) 10-2023-0059902
Aug. 11, 2023 (KR) 10-2023-0105628

(51) Int. Cl. H10K 59/38; B82Y 20/00; B82Y 40/00

(52) U.S. Cl. CPC H10K 59/38; B82Y 20/00; B82Y 40/00

(57) ABSTRACT

The present application relates to a display apparatus and a method of manufacturing a display apparatus. In a method of manufacturing a display apparatus, the method includes: locating a bank comprising a first central opening and a second central opening on an upper substrate; locating a first quantum dot layer in the first central opening; locating a second quantum dot layer in the second central opening; and irradiating light having a wavelength of 520 nm or more to the second quantum dot layer.

### CROSS-REFERENCE TO RELATED APPLICATION

The present application claims priority to and the benefit of Korean Patent Application No. 10-2023-0039174, filed on Mar. 24, 2023, Korean Patent Application No. 10-2023-0059902, filed May 9, 2023, and Korean Patent Application No. 10-2023-0105628, filed Aug. 11, 2023, in the Korean Intellectual Property Office, the entire content of each of which is incorporated herein by reference.

### BACKGROUND

### 1. Field

Aspects of one or more embodiments relate to an apparatus and method.

### 2. Description of Related Art

Mobility-based electronic devices are widely used. Recently, tablet personal computers (PCs), in addition to small electronic devices such as mobile phones, have been widely used as mobile electronic devices.

A mobile electronic device includes a display for providing visual information such as an image or a video to a user, in order to support various functions. Recently, as other components for driving a display have been miniaturized, the proportion of the display in an electronic device has gradually increased, and a structure that is bendable from a flat state by a certain angle has been developed.

The above information disclosed in this Background section is only for enhancement of understanding of the background and therefore the information discussed in this Background section does not necessarily constitute prior art.

### SUMMARY

Aspects of one or more embodiments relate to an apparatus and method, and for example, to a display apparatus and a method of manufacturing the same.

A display apparatus may use a color filter and a quantum dot material to provide a clear image. In this case, color reproducibility of light passing through the quantum dot material and the color filter may be important in forming an image similar to a real object. Aspects of one or more embodiments include a display apparatus for providing a clear image and a method of manufacturing the display apparatus.

Additional aspects will be set forth in part in the description which follows and, in part, will be apparent from the description, or may be learned by practice of the presented embodiments.

According to one or more embodiments, a method of manufacturing a display apparatus includes locating a bank including a first central opening and a second central opening on an upper substrate, locating a first quantum dot layer in the first central opening, locating a second quantum dot layer in the second central opening, and irradiating light having a wavelength of 520 nm or more to the second quantum dot layer.

According to some embodiments, the method may further include locating a lamp to face the upper substrate, and locating a filter between the lamp and the second quantum dot layer.

According to some embodiments, the filter may be configured to transmit light having a wavelength of 520 nm or more.

According to some embodiments, the lamp may be configured to emit white light.

According to some embodiments, the method may further include locating a blocking member between the lamp and the first quantum dot layer.

According to some embodiments, an intensity of the light may be 5 lux or more and 40 lux or less.

According to some embodiments, the light may be irradiated to the second quantum dot layer for a time ranging from 70 hours or more to 100 hours or less.

According to some embodiments, the second quantum dot layer may include a quantum dot including an AIGS core.

According to some embodiments, the first quantum dot layer and the second quantum dot layer may be supplied into the first central opening and the second central opening by using an inkjet printing method, respectively.

According to some embodiments, the method may further include locating a color filter layer between the upper substrate and the bank.

According to some embodiments, the method may further include locating a capping layer on the first quantum dot layer and the second quantum dot layer.

According to some embodiments, a method of manufacturing a display apparatus includes locating a bank including a first central opening and a second central opening on a light-emitting panel, locating a first quantum dot layer in the first central opening, locating a second quantum dot layer in the second central opening, and irradiating light having a wavelength of 520 nm or more to the second quantum dot layer.

According to some embodiments, the method may further include locating a lamp to face the light-emitting panel, and locating a filter between the lamp and the second quantum dot layer.

According to some embodiments, the filter may be configured to transmit light having a wavelength of 520 nm or more.

According to some embodiments, the lamp may be configured to emit white light.

According to some embodiments, the method may further include locating a blocking member between the lamp and the first quantum dot layer.

According to some embodiments, an intensity of the light may be 5 lux or more and 40 lux or less.

According to some embodiments, the light may be irradiated to the second quantum dot layer for a time ranging from 70 hours or more to 100 hours or less.

According to some embodiments, the second quantum dot layer may include a quantum dot including an AIGS core.

According to some embodiments, the method may further include locating a capping layer on the first quantum dot layer and the second quantum dot layer.

According to some embodiments, a display apparatus includes a display panel including sub-pixels, and a color panel located on the display panel and including quantum dot layers located to correspond to the sub-pixels, wherein at least one of the quantum dot layers includes a quantum dot including an AIGS core, wherein the AIGS core includes at least one of InxGa₍₁₋ₓ₎P, AgInxGa₍₁₋ₓ₎S₂, AgInS₂, AgGaS₂, CuInS₂, CuInSe₂, CuGaS₂, CuGaSe₂, or ZnSe, ZnTexSe₍₁₋ₓ₎ (where x is a rational number greater than 0 and less than 1).

According to some embodiments, light passing through a portion of the color panel where the quantum dot layer is located may be green.

According to some embodiments, a tau of a decay time of light passing through the quantum dot layer may be 30 or more and 80 or less.

According to some embodiments, the display apparatus may further include a capping layer located on the quantum dot layer.

According to some embodiments, the display apparatus may further include a color filter located to correspond to the quantum dot layer.

Other aspects, features, and characteristics of some embodiments of the present disclosure will become more apparent from the drawings, the claims, and the

### DETAILED DESCRIPTION

These general and specific embodiments may be implemented by using a system, a method, a computer program, or a combination thereof.

### BRIEF DESCRIPTION OF THE DRAWINGS

The above and other aspects, features, and characteristics of certain embodiments will be more apparent from the following description taken in conjunction with the accompanying drawings, in which:

FIG. 1 is a perspective view illustrating a display apparatus, according to some embodiments;

FIG. 2 is a cross-sectional view schematically illustrating the display apparatus of FIG. 1 according to some embodiments;

FIG. 3 is a cross-sectional view illustrating a part of a display apparatus, according to some embodiments;

FIGS. 4A to 4C are cross-sectional views illustrating a method of manufacturing a color panel of FIG. 3 according to some embodiments;

FIG. 4D is a graph illustrating a wavelength and an intensity of light passing through a filter of FIG. 4C according to some embodiments;

FIG. 4E is a cross-sectional view illustrating a method of manufacturing the color panel of FIG. 3 according to some embodiments;

FIG. 4F is a cross-sectional view illustrating a method of manufacturing a display apparatus, according to some embodiments;

FIG. 5 is a cross-sectional view illustrating a display apparatus, according to some embodiments;

FIGS. 6A to 6D are cross-sectional views illustrating a method of manufacturing the display apparatus of FIG. 5 according to some embodiments;

FIG. 7 is a graph illustrating an absorption increase rate and an efficiency increase rate between the display apparatus of FIG. 3 or 5 and an existing display apparatus;

FIG. 8 is a graph illustrating an absorptance for each wavelength of the display apparatus of FIG. 3 or 5 according to some embodiments; and

FIGS. 9A and 9B are graphs illustrating an intensity of light over time when light is irradiated to a second quantum dot layer according to some embodiments.

### DETAILED DESCRIPTION

Reference will now be made in more detail to aspects of some embodiments, which are illustrated in the accompanying drawings, wherein like reference numerals refer to like elements throughout. In this regard, embodiments according to the present disclosure may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or any combination or variation thereof.

As the disclosure allows for various changes and numerous embodiments, certain embodiments will be illustrated in the drawings and described in the detailed description. Effects and features of the disclosure, and methods for achieving them will be clarified with reference to embodiments described below in more detail with reference to the drawings. However, the disclosure is not limited to the following embodiments and may be embodied in various forms.

Hereinafter, embodiments will be described in more detail with reference to the accompanying drawings, wherein the same or corresponding elements are denoted by the same reference numerals throughout and a repeated description thereof is omitted.

Although the terms “first,” “second,” etc. may be used to describe various elements, these elements should not be limited by these terms. These terms are only used to distinguish one element from another.

As used herein, the singular forms “a,” “an,” and “the” are intended to include the plural forms as well, unless the context clearly indicates otherwise.

It will be understood that the terms “including,” and “having,” are intended to indicate the existence of the features or elements described in the specification, and are not intended to preclude the possibility that one or more other features or elements may exist or may be added.

It will be further understood that, when a layer, region, or component is referred to as being “on” another layer, region, or component, it may be directly on the other layer, region, or component, or may be indirectly on the other layer, region, or component with intervening layers, regions, or components therebetween.

Sizes of components in the drawings may be exaggerated or contracted for convenience of explanation. For example, because sizes and thicknesses of elements in the drawings are arbitrarily illustrated for convenience of explanation, the disclosure is not limited thereto.

In the following embodiments, the x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

When a certain embodiment may be implemented differently, a specific process order may be different from the described order. For example, two consecutively described processes may be performed substantially at the same time or may be performed in an order opposite to the described order.

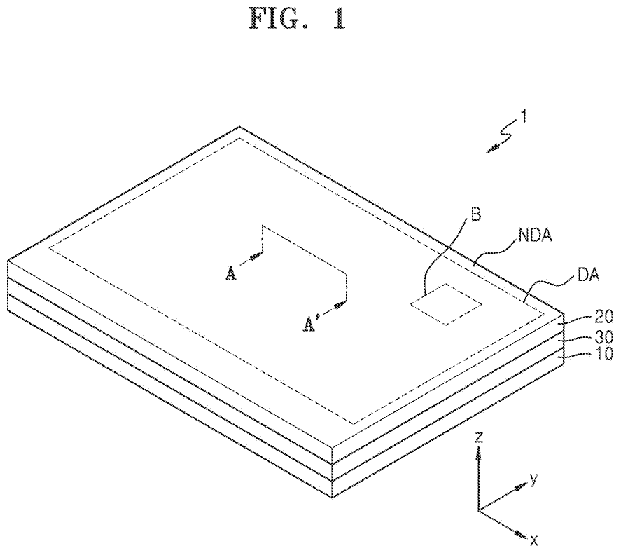

FIG. 1 is a perspective view illustrating a display apparatus, according to some embodiments.

Referring to FIG. 1, a display apparatus 1 may display an image. The display apparatus 1 may display images through a plurality of sub-pixels located in a display area DA. Each sub-pixel of the display apparatus 1 may be an area where light of a certain color may be emitted. The display apparatus 1 may display images by using light emitted from the plurality of sub-pixels. For example, a sub-pixel may emit red, light, green light, or blue light. Alternatively, a sub-pixel may emit red light, green light, blue light, or white light.

A non-display area NDA may at least partially surround the display area DA. According to some embodiments, the non-display area NDA may entirely surround (e.g., in a periphery or outside a footprint of) the display area DA. The non-display area NDA may be an area where images are not displayed.

The display area DA may have a polygonal shape including a quadrangular shape as shown in FIG. 1. For example, the display area DA may have a rectangular shape in which a horizontal length is greater than a vertical length, a rectangular shape in which a horizontal length is less than a vertical length, or a square shape. Embodiments according to the present disclosure are not limited thereto, however. For example, according to some embodiments, the display area DA may have more than four sides and/or one or more curved sides or edges. Alternatively, the display area DA may have any of various shapes such as an elliptical shape or a circular shape. According to some embodiments, the display apparatus 1 may include a light-emitting panel 10, a color panel 20, and a filling layer 30. The light-emitting panel 10, the filling layer 30, and the color panel 20 may be stacked in a thickness direction (e.g., a z direction).

The display apparatus 1 having the above structure may be included in a mobile phone, a television, an advertisement board, a monitor, a tablet personal computer (PC), or a laptop.

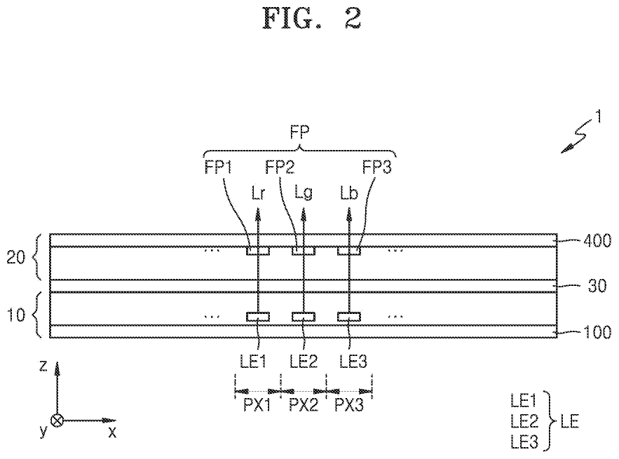

FIG. 2 is a cross-sectional view schematically illustrating the display apparatus of FIG. 1.

Referring to FIG. 2, the display apparatus 1 may include a first sub-pixel PX1, a second sub-pixel PX2, and a third sub-pixel PX3. The first sub-pixel PX1, the second sub-pixel PX2, and the third sub-pixel PX3 may be sub-pixels that emit light of different colors. For example, the first sub-pixel PX1 may emit red light Lr, the second sub-pixel PX2 may emit green light Lg, and the third sub-pixel PX3 may emit blue light Lb.

The display apparatus 1 may include the light-emitting panel 10, the color panel 20, and the filling layer 30. The light-emitting panel 10 may include a lower substrate 100 and a light-emitting device LE. The light-emitting device LE may be, for example, an organic light-emitting diode. According to some embodiments, each of the first sub-pixel PX1, the second sub-pixel PX2, and the third sub-pixel PX3 may include the light-emitting device LE. For example, the first sub-pixel PX1 may include a first light-emitting device LE1. The first light-emitting device LE1 may be a first organic light-emitting diode. The second sub-pixel PX2 may include a second light-emitting device LE2. The second light-emitting device LE2 may be a second organic light-emitting diode. The third sub-pixel PX3 may include a third light-emitting device LE3. The third light-emitting device LE3 may be a third organic light-emitting diode.

The first light-emitting device LE1, the second light-emitting device LE2, and the third light-emitting device LE3 may emit light of the same color. According to some embodiments, the first light-emitting device LE1, the second light-emitting device LE2, and the third light-emitting device LE3 may emit blue light.

The color panel 20 may include an upper substrate 400 and a filter unit FP. According to some embodiments, the filter unit FP may include a first filter unit FP1, a second filter unit FP2, and a third filter unit FP3. Light emitted by the first light-emitting device LE1 may be emitted as red light Lr through the first filter unit FP1. Light emitted by the second light-emitting device LE2 may be emitted as green light Lg through the second filter unit FP2. Light emitted by the third light-emitting device LE3 may be emitted as blue light Lb through the third filter unit FP3.

The filter unit FP may include a functional layer and a color filter layer. According to some embodiments, the functional layer may include a first quantum dot layer, a second quantum dot layer, and a transmissive layer. According to some embodiments, the color filter layer may include a first color filter, a second color filter, and a third color filter. The first filter unit FP1 may include the first quantum dot layer and the first color filter. The second filter unit FP2 may include the second quantum dot layer and the second color filter. The third filter unit FP3 may include the transmissive layer and the third color filter.

The filter unit FP may be located directly on the upper substrate 400. In this case, when the filter unit FP is located ‘directly on the upper substrate 400’, it may mean that the color panel 20 is manufactured by directly forming the first filter unit FP1, the second filter unit FP2, and the third filter unit FP3 on the upper substrate 400. Next, the color panel 20 may be adhered to the light-emitting panel 10 so that the first filter unit FP1, the second filter unit FP2, and the third filter unit FP3 respectively face the first light-emitting device LE1, the second light-emitting device LE2, and the third light-emitting device LE3.

The filling layer 30 may be located between the light-emitting panel 10 and the color panel 20. That is, the filling layer 30 may be above the light-emitting panel 10 and below the color panel 20. The filling layer 30 may be used to attach the light-emitting panel 10 to the color panel 20. According to some embodiments, the filling layer 30 may include a thermosetting or photocurable filler.

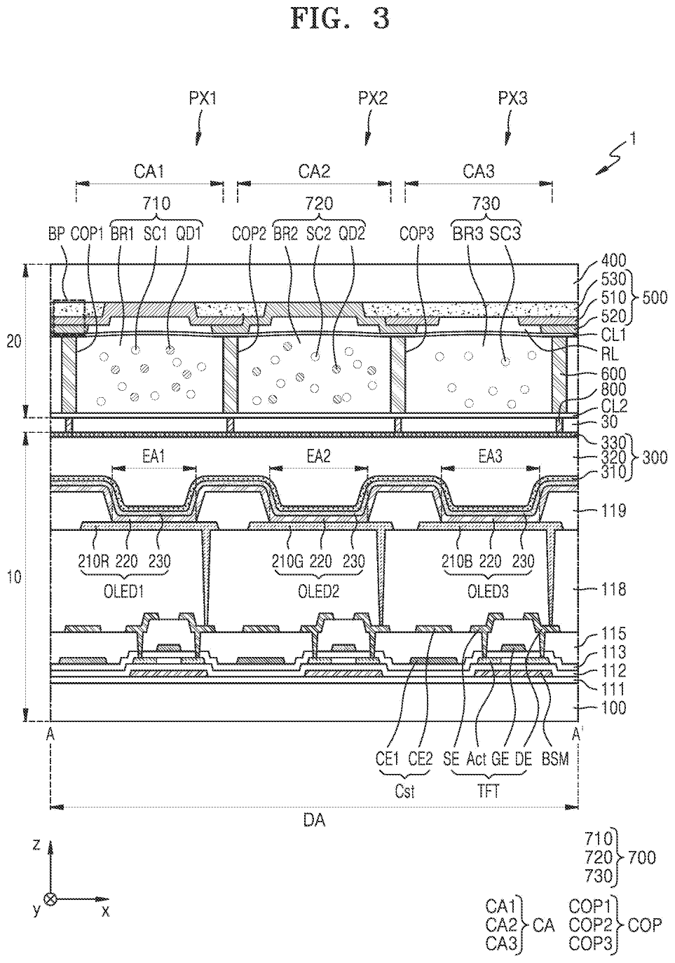

FIG. 3 is a cross-sectional view illustrating a part of a display apparatus, according to some embodiments. FIG. 3 is a cross-sectional view taken along a line A-A′ of FIG. 1.

Referring to FIG. 3, the display apparatus 1 may include the first sub-pixel PX1, the second sub-pixel PX2, and the third sub-pixel PX3 located in the display area DA. The first sub-pixel PX1, the second sub-pixel PX2, and the third sub-pixel PX3 may emit different light. For example, the first sub-pixel PX1 may emit red light, the second sub-pixel PX2 may emit green light, and the third sub-pixel PX3 may emit blue light.

According to some embodiments, the display apparatus 1 may include more sub-pixels (e.g., any suitable number of sub-pixels according to the design and size of the display apparatus 1). Although the first sub-pixel PX1, the second sub-pixel PX2, and the third sub-pixel PX3 are adjacent to each other in FIG. 3, according to some embodiments, the first sub-pixel PX1, the second sub-pixel PX2, and the third sub-pixel PX3 may not be adjacent to each other.

The display apparatus 1 may include the light-emitting panel 10, the color panel 20, and the filling layer 30. The light-emitting panel 10 may include the lower substrate 100, and a light-emitting device located on the lower substrate 100 and including an emission layer 220. The light-emitting device may be an organic light-emitting diode. According to some embodiments, the light-emitting panel 10 may include a first organic light-emitting diode OLED1, a second organic light-emitting diode OLED2, and a third organic light-emitting diode OLED3 located on the lower substrate 100. The first organic light-emitting diode OLED1, the second organic light-emitting diode OLED2, and the third organic light-emitting diode OLED3 may include the emission layer 220.

A stacked structure of the light-emitting panel 10 will now be described in more detail. According to some embodiments, the light-emitting panel 10 may include the lower substrate 100, a first buffer layer 111, a bias electrode BSM, a second buffer layer 112, a thin-film transistor TFT, a storage capacitor Cst, a gate insulating layer 113, an interlayer insulating layer 115, a planarization layer 118, the light-emitting device, and an encapsulation layer 300. The thin-film transistor TFT may include a semiconductor layer Act, a gate electrode GE, a source electrode SE, and a drain electrode DE. The storage capacitor Cst may include a first electrode CE1 and a second electrode CE2.

The lower substrate 100 may include a glass material, a ceramic material, a metal material, or a flexible or bendable material. When the lower substrate 100 is flexible or bendable, the lower substrate 100 may include a polymer resin such as a polyethersulfone, polyacrylate, polyetherimide, polyethylene naphthalate, polyethylene terephthalate, polyphenylene sulfide, polyarylate, polyimide, polycarbonate, or cellulose acetate propionate. The lower substrate 100 may have a single or multi-layer structure including the above material, and when the lower substrate 100 has a multi-layer structure, the lower substrate 100 may further include an inorganic layer. According to some embodiments, the lower substrate 100 may have a structure including an organic material, an inorganic material, and an organic material.

A barrier layer may be further provided between the lower substrate 100 and the first buffer layer 111. The barrier layer may prevent, reduce, or minimize impurities or contaminants, etc. from the lower substrate 100 from penetrating into the semiconductor layer Act. The barrier layer may include an inorganic material such as oxide or nitride, an organic material, or a combination of an organic material and an inorganic material, and may have a single or multi-layer structure including an inorganic material and an organic material.

The bias electrode BSM may be located on the first buffer layer 111 to correspond to the thin-film transistor TFT. According to some embodiments, a voltage may be applied to the bias electrode BSM. Also, the bias electrode BSM may prevent external light from reaching the semiconductor layer Act. Accordingly, characteristics of the thin-film transistor TFT may be stabilized. The bias electrode BSM may be omitted when necessary.

The semiconductor layer Act may be located on the second buffer layer 112. The semiconductor layer Act may include amorphous silicon or polysilicon. According to some embodiments, the semiconductor layer Act may include an oxide of at least one material selected from the group consisting of indium (In), gallium (Ga), stannum (Sn), zirconium (Zr), vanadium (V), hafnium (Hf), cadmium (Cd), germanium (Ge), chromium (Cr), titanium (Ti), aluminum (Al), cesium (Cs), cerium (Ce), and zinc (Zn). In some embodiments, the semiconductor layer Act may be formed of a Zn oxide-based material such as Zn oxide, In—Zn oxide, or Ga—In—Zn oxide. According to some embodiments, the semiconductor layer Act may be formed of an In—Ga—Zn—O (IGZO), In—Sn—Zn—O (ITZO), or In—Ga—Sn—Zn—O (IGTZO) semiconductor containing a metal such as indium (In), gallium (Ga), or tin (Sn) in ZnO. The semiconductor layer Act may include a channel region, and a source region and a drain region located on both sides of the channel region. The semiconductor layer Act may have a single or multi-layer structure.

The gate electrode GE may be located on the semiconductor layer Act with the gate insulating layer 113 therebetween. The gate electrode GE may at least partially overlap the semiconductor layer Act. The gate electrode GE may include molybdenum (Mo), aluminum (Al), copper (Cu), or titanium (Ti), and may have a single or multi-layer structure. For example, the gate electrode GE may have a single-layer structure including Mo. The first electrode CE1 of the storage capacitor Cst may be located on the same layer as the gate electrode GE. The first electrode CE1 and the gate electrode GE may include the same material.

Although the gate electrode GE of the thin-film transistor TFT and the first electrode CE1 of the storage capacitor Cst are separately located in FIG. 3, the storage capacitor Cst may overlap the thin-film transistor TFT. In this case, the gate electrode GE of the thin-film transistor TFT may function as the first electrode CE1 of the storage capacitor Cst.

The interlayer insulating layer 115 may be provided to cover the gate electrode GE and the first electrode CE1 of the storage capacitor Cst. The interlayer insulating layer 115 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). Zinc oxide (ZnOₓ) may include zinc oxide (ZnO) and/or zinc peroxide (ZnO₂).

The second electrode CE2 of the storage capacitor Cst, the source electrode SE, and the drain electrode DE may be located on the interlayer insulating layer 115. Each of the second electrode CE2 of the storage capacitor Cst, the source electrode SE, and the drain electrode DE may include a conductive material such as Mo, Al, Cu, or Ti, and may have a single or multi-layer structure including the above material. For example, each of the second electrode CE2, the source electrode SE, and the drain electrode DE may have a multi-layer structure including Ti/Al/Ti. The source electrode SE and the drain electrode DE may be connected to the source region or the drain region of the semiconductor layer Act through a contact hole.

The second electrode CE2 and the first electrode CE1 of the storage capacitor Cst overlap each other with the interlayer insulating layer 115 therebetween to constitute the storage capacitor Cst. In this case, the interlayer insulating layer 115 may function as a dielectric layer of the storage capacitor Cst.

The planarization layer 118 may be located on the second electrode CE2 of the storage capacitor Cst, the source electrode SE, and the drain electrode DE. The planarization layer 118 may have a single or multi-layer structure formed of an organic material, and may provide a flat top surface. The planarization layer 118 may include benzocyclobutene (BCB), polyimide, hexamethyldisiloxane (HMDSO), a general-purpose polymer such as polymethyl methacrylate (PMMA) or polystyrene (PS), a polymer derivative having a phenol-based group, an acrylic polymer, an imide-based polymer, an aryl ether-based polymer, an amide-based polymer, a fluorinated polymer, a p-xylene-based polymer, a vinyl alcohol-based polymer, or a blend thereof.

The light-emitting device may be located on the planarization layer 118. The light-emitting device may include a pixel electrode, the emission layer 220, and a counter electrode 230. According to some embodiments, the first organic light-emitting diode OLED1, the second organic light-emitting diode OLED2, and the third organic light-emitting diode OLED3 may be located on the planarization layer 118. The first organic light-emitting diode OLED1, the second organic light-emitting diode OLED2, and the third organic light-emitting diode OLED3 may respectively include a first pixel electrode 210R, a second pixel electrode 210G, and a third pixel electrode 210B. According to some embodiments, the first organic light-emitting diode OLED1, the second organic light-emitting diode OLED2, and the third organic light-emitting diode OLED3 may commonly include the emission layer 220 and the counter electrode 230.

The first pixel electrode 210R, the second pixel electrode 210G, and the third pixel electrode 210B may be located on the planarization layer 118. Each of the first pixel electrode 210R, the second pixel electrode 210G, and the third pixel electrode 210B may be connected to the thin-film transistor TFT. Each of the first pixel electrode 210R, the second pixel electrode 210G, and the third pixel electrode 210B may be a (semi-)transmissive electrode or a reflective electrode. In some embodiments, each of the first pixel electrode 210R, the second pixel electrode 210G, and the third pixel electrode 210B may include a reflective layer formed of Ag, Mg, Al, Pt, Pd, Au, Ni, Nd, Ir, Cr, or a compound thereof and a transparent or a semi-transparent electrode layer formed on the reflective layer. The transparent or semi-transparent electrode layer may include at least one selected from the group consisting of indium tin oxide (ITO), indium zinc oxide (IZO), zinc oxide (ZnO), indium oxide (In₂O₃), indium gallium oxide (IGO), and aluminum zinc oxide (AZO). According to some embodiments, each of the first pixel electrode 210R, the second pixel electrode 210G, and the third pixel electrode 210B may formed of ITO/Ag/ITO.

A pixel-defining film 119 may be located on the planarization layer 118. The pixel-defining film 119 may include openings through which central portions of the first pixel electrode 210R, the second pixel electrode 210G, and the third pixel electrode 210B are respectively exposed. The pixel-defining film 119 may cover edges of the first pixel electrode 210R, the second pixel electrode 210G, and the third pixel electrode 210B. The pixel-defining film 119 may increase a distance between an edge of each of the first pixel electrode 210R, the second pixel electrode 210G, and the third pixel electrode 210B and the counter electrode 230 on the first pixel electrode 210R, the second pixel electrode 210G, and the third pixel electrode 210B, to prevent an arc or the like from occurring at the edge of each of the first pixel electrode 210R, the second pixel electrode 210G, and the third pixel electrode 210B. The pixel-defining film 119 may be formed of at least one organic insulating material selected from the group consisting of polyimide, polyamide, an acrylic resin, benzocyclobutene, and a phenolic resin by using spin coating or the like.

The emission layer 220 of the first organic light-emitting diode OLED1, the second organic light-emitting diode OLED2, and the third organic light-emitting diode OLED3 may include an organic material including a fluorescent or phosphorescent material that emits red light, green light, blue light, or white light. The emission layer 220 may be formed of a low molecular weight organic material or a high molecular weight organic material. A functional layer such as a hole transport layer (HTL), a hole injection layer (HIL), an electron transport layer (ETL), or an electron injection layer (EIL) may be selectively further located under or over the emission layer 220. Although the emission layer 220 is integrally provided over the first pixel electrode 210R, the second pixel electrode 210G, and the third pixel electrode 210B in FIG. 3, the disclosure is not limited thereto, and various modifications may be made. For example, the emission layer 220 may be located to correspond to each of the first pixel electrode 210R, the second pixel electrode 210G, and the third pixel electrode 210B.

Although the emission layer 220 may include a layer that is integrally provided over the first pixel electrode 210R, the second pixel electrode 210G, and the third pixel electrode 210B as described above, the emission layer 220 may include a layer patterned to correspond to each of the first pixel electrode 210R, the second pixel electrode 210G, and the third pixel electrode 210B according to some embodiments. In any case, the emission layer 220 may be a first color emission layer. The first color emission layer may be integrally provided over the first pixel electrode 210R, the second pixel electrode 210G, and the third pixel electrode 210B, or may be patterned to correspond to each of the first pixel electrode 210R, the second pixel electrode 210G, and the third pixel electrode 210B according to some embodiments. The first-color emission layer may emit light of a first wavelength band, for example, light having a wavelength of about 450 nm to about 495 nm.

The counter electrode 230 may be located on the emission layer 220 to correspond to the first pixel electrode 210R, the second pixel electrode 210G, and the third pixel electrode 210B. The counter electrode 230 may be integrally provided in a plurality of organic light-emitting diodes. According to some embodiments, the counter electrode 230 may be a transparent or semi-transparent electrode, and may include a metal thin film having a low work function including lithium (Li), calcium (Ca), aluminum (Al), silver (Ag), magnesium (Mg), or a compound thereof, or a material with multilayer structure such as LiF/Ca or LiF/Al. Also, a transparent conductive oxide (TCO) film such as ITO, IZO, ZnO, or In₂O₃ may be further located on the metal thin film.

According to some embodiments, first light may be generated in a first emission area EA1 of the first organic light-emitting diode OLED1 and may be emitted to the outside. The first emission area EA1 may be defined as a portion of the first pixel electrode 210R exposed through the opening of the pixel-defining film 119. Second light may be generated in a second emission area EA2 of the second organic light-emitting diode OLED2 and may be emitted to the outside. The second emission area EA2 may be defined as a portion of the second pixel electrode 210G exposed through the opening of the pixel-defining film 119. Third light may be generated in a third emission area EA3 of the third organic light-emitting diode OLED3 and may be emitted to the outside. The third emission area EA3 may be defined as a portion of the third pixel electrode 210B exposed through the opening of the pixel-defining film 119.

The first emission area EA1, the second emission area EA2, and the third emission area EA3 may be spaced apart from each other. A portion of the display area DA other than the first emission area EA1, the second emission area EA2, and the third emission area EA3 may be a non-emission area. The first emission area EA1, the second emission area EA2, and the third emission area EA3 may be divided by the non-emission area. In a plan view, the first emission area EA1, the second emission area EA2, and the third emission area EA3 may be arranged in any of various arrangements such as a stripe arrangement or a pentile arrangement. In a plan view, each of a shape of the first emission area EA1, a shape of the second emission area EA2, and a shape of the third emission area EA3 may be any of a polygonal shape, a circular shape, and an elliptical shape.

A spacer for preventing or reducing mask damage may be further provided on the pixel-defining film 119. The spacer may be integrally provided with the pixel-defining film 119. For example, the spacer and the pixel-defining film 119 may be simultaneously formed in the same process using a halftone mask process.

An encapsulation layer 300 may be located on a light-emitting device and may cover the light-emitting device. Because the first organic light-emitting diode OLED1, the second organic light-emitting diode OLED2, and the third organic light-emitting diode OLED3 may be relatively easily damaged by external moisture or oxygen, the first organic light-emitting diode OLED1, the second organic light-emitting diode OLED2, and the third organic light-emitting diode OLED3 may be covered and protected by the encapsulation layer 300. The encapsulation layer 300 may cover the display area DA and may extend to the outside of the display area DA. The encapsulation layer 300 may include at least one organic encapsulation layer and at least one inorganic encapsulation layer. For example, the encapsulation layer 300 may include a first inorganic encapsulation layer 310, an organic encapsulation layer 320, and a second inorganic encapsulation layer 330.

Because the first inorganic encapsulation layer 310 extends along a structure under the first inorganic encapsulation layer 310, a top surface of the first inorganic encapsulation layer 310 may not be flat. The organic encapsulation layer 320 may cover the first inorganic encapsulation layer 310, and unlike the first inorganic encapsulation layer 310, the organic encapsulation layer 320 may have a substantially flat top surface.

Each of the first inorganic encapsulation layer 310 and the second inorganic encapsulation layer 330 may include at least one inorganic material from among aluminum oxide (Al₂O₃), titanium oxide (TiO₂), tantalum oxide (Ta₂O₅), hafnium oxide (HfO₂), zinc oxide (ZnOₓ), silicon oxide (SiO₂), silicon nitride (SiNₓ), and silicon oxynitride (SiON). The organic encapsulation layer 320 may include a polymer-based material. Examples of the polymer-based material may include an acrylic resin, an epoxy resin, polyimide, and polyethylene. According to some embodiments, the organic encapsulation layer 320 may include acrylate.

Even when cracks occur in the encapsulation layer 300, the cracks may not be connected between the first inorganic encapsulation layer 310 and the organic encapsulation layer 320 or between the organic encapsulation layer 320 and the second inorganic encapsulation layer 330 due to the above multi-layer structure. Accordingly, the formation of a path through which external moisture, contaminants, or oxygen penetrates into the display area DA may be prevented, reduced, or minimized. According to some embodiments, other layers such as a capping layer may be located between the first inorganic encapsulation layer 310 and the counter electrode 230 when necessary.

The color panel 20 may include the upper substrate 400, a color filter layer 500, a refractive layer RL, a first capping layer CL1, a bank 600, a functional layer 700, and a second capping layer CL2. The upper substrate 400 may be located on the lower substrate 100 with the light-emitting device therebetween. The upper substrate 400 may be located on the first organic light-emitting diode OLED1, the second organic light-emitting diode OLED2, and the third organic light-emitting diode OLED3.

The upper substrate 400 may include a central area CA overlapping the light-emitting device. According to some embodiments, the central area CA may include a first central area CA1, a second central area CA2, and a third central area CA3. In a plan view, the first central area CA1 may overlap the first organic light-emitting diode OLED1 and/or the first emission area EA1. In a plan view, the second central area CA2 may overlap the second organic light-emitting diode OLED2 and/or the second emission area EA2. In a plan view, the third central area CA3 may overlap the third organic light-emitting diode OLED3 and/or the third emission area EA3.

The upper substrate 400 may include glass, a metal, or a polymer resin. When the upper substrate 400 is flexible or bendable, the upper substrate 400 may include a polymer resin such as a polyethersulfone, polyacrylate, polyetherimide, polyethylene naphthalate, polyethylene terephthalate, polyphenylene sulfide, polyarylate, polyimide, polycarbonate, or cellulose acetate propionate. According to some embodiments, the upper substrate 400 may have a multi-layer structure including two layers each including such a polymer resin and a barrier layer including an inorganic material such as silicon oxide (SiO₂), silicon nitride (SiNₓ), or silicon oxynitride (SiON) located between the two layers.

The color filter layer 500 may be located on a bottom surface of the upper substrate 400 in a direction from the upper substrate 400 to the lower substrate 100. The color filter layer 500 may include a first color filter 510, a second color filter 520, and a third color filter 530. The first color filter 510 may be located in the first central area CA1. The second color filter 520 may be located in the second central area CA2. The third color filter 530 may be located in the third central area CA3. Each of the first color filter 510, the second color filter 520, and the third color filter 530 may be formed of a photosensitive resin material. Each of the first color filter 510, the second color filter 520, and the third color filter 530 may include a dye producing a unique color. The first color filter 510 may transmit only light having a wavelength of 630 nm to 780 nm, the second color filter 520 may transmit only light having a wavelength of 495 nm to 570 nm, and the third color filter 530 may transmit only light having a wavelength of 450 nm to 495 nm.

The color filter layer 500 may reduce the reflection of external light of the display apparatus 1. For example, when external light reaches the first color filter 510, only light having the preset wavelength may pass through the first color filter 510 and light having other wavelengths may be absorbed by the first color filter 510. Accordingly, from among external light incident on the display apparatus 1, only light having the preset wavelength may pass through the first color filter 510, and part of the light may be reflected by the counter electrode 230 and/or the first pixel electrode 210R under the first color filter 510 and then may be emitted back to the outside. From among external light incident on a location where the first sub-pixel PX1 is located, only part is reflected to the outside, and thus, the reflection of the external light may be reduced. The same description may apply to the second color filter 520 and the third color filter 530.

The first color filter 510, the second color filter 520, and the third color filter 530 may overlap each other. The first color filter 510, the second color filter 520, and the third color filter 530 may overlap each other between any one of the central areas CA and another one of the central areas CA. For example, the first color filter 510, the second color filter 520, and the third color filter 530 may overlap each other between the first central area CA1 and the second central area CA2. In this case, the third color filter 530 may be located between the first central area CA1 and the second central area CA2. The first color filter 510 may extend from the first central area CA1 and overlap the third color filter 530. The second color filter 520 may extend from the second central area CA2 and overlap the third color filter 530.

The first color filter 510, the second color filter 520, and the third color filter 530 may overlap between the second central area CA2 and the third central area CA3. The first color filter 510 may be located between the second central area CA2 and the third central area CA3. The second color filter 520 may extend from the second central area CA2 and overlap the first color filter 510. The third color filter 530 may extend from the third central area CA3 and overlap the first color filter 510.

The first color filter 510, the second color filter 520, and the third color filter 530 may overlap each other between the third central area CA3 and the first central area CA1. The second color filter 520 may be located between the third central area CA3 and the first central area CA1. The third color filter 530 may extend from the third central area CA3 and overlap the second color filter 520. The first color filter 510 may extend from the first central area CA1 and overlap the second color filter 520.

The first color filter 510, the second color filter 520, and the third color filter 530 may overlap each other to constitute a light blocking unit BP. Accordingly, the color filter layer 500 may prevent or reduce color mixing even without a separate light blocking member.

According to some embodiments, the third color filter 530 may be first stacked on the upper substrate 400. This is because the third color filter 530 may reduce a reflectance of the display apparatus 1 by absorbing part of external light incident on the upper substrate 400, and light reflected by the third color filter 530 is hardly seen by a user.

A refractive layer RL may be located in the central area CA. The refractive layer RL may be located in each of the first central area CA1, the second central area CA2, and the third central area CA3. The refractive layer RL may include an organic material. According to some embodiments, a refractive index of the refractive layer RL may be less than a refractive index of the first capping layer CL1. According to some embodiments, a refractive index of the refractive layer RL may be less than a refractive index of the color filter layer 500. Accordingly, the refractive layer RL may concentrate light.

The first capping layer CL1 may be located on the refractive layer RL and the color filter layer 500. According to some embodiments, the first capping layer CL1 may be located between the color filter layer 500 and the functional layer 700. The first capping layer CL1 may protect the refractive layer RL and the color filter layer 500. The first capping layer CL1 may prevent or reduce impurities such as external moisture and/or air from penetrating into and damaging the refractive layer RL and/or the color filter layer 500. The first capping layer CL1 may include an inorganic material.

The bank 600 may be located on the first capping layer CL1. According to some embodiments, the bank 600 may be located on the upper substrate 400. The bank 600 may be located on the bottom surface of the upper substrate 400 facing the lower substrate 100. The bank 600 may include an organic material. When necessary, the bank 600 may include a light blocking material to function as a light blocking layer. The light blocking material may include at least one of, for example, a black pigment, a black dye, black particles, or metal particles.

The bank 600 may include a plurality of openings. For example, a central opening COP may be formed in the bank 600. The central opening COP may overlap the central area CA. According to some embodiments, a plurality of central openings COP may overlap the central areas CA. For example, a first central opening COP1 may overlap the first central area CA1. A second central opening COP2 may overlap the second central area CA2. A third central opening COP3 may overlap the third central area CA3.

The functional layer 700 may be located in the central opening COP. The functional layer 700 may fill the central opening COP. According to some embodiments, the functional layer 700 may include at least one of a color conversion material or a scatterer. According to some embodiments, the color conversion material may be quantum dots. According to some embodiments, the functional layer 700 may include a first quantum dot layer 710, a second quantum dot layer 720, and a transmissive layer 730.

The first quantum dot layer 710 may be located in the first central opening COP1. The first quantum dot layer 710 may overlap the first central area CA1. The first quantum dot layer 710 may fill the first central opening COP1. The first quantum dot layer 710 may overlap the first emission area EA1. The first sub-pixel PX1 may include the first organic light-emitting diode OLED1 and the first quantum dot layer 710.

The first quantum dot layer 710 may convert light of a first wavelength band generated by the emission layer 220 on the first pixel electrode 210R into light of a second wavelength band. For example, when light having a wavelength of 450 nm to 495 nm is generated by the emission layer 220 on the first pixel electrode 210R, the first quantum dot layer 710 may convert the light into light having a wavelength of 630 nm to 780 nm. Accordingly, in the first sub-pixel PX1, the light having a wavelength of 630 nm to 780 nm may be emitted to the outside through the upper substrate 400. According to some embodiments, the first quantum dot layer 710 may include first quantum dots QD1, a first scatterer SC1, and a first base resin BR1. The first quantum dots QD1 and the first scatterer SC1 may be dispersed in the first base resin BR1.

The second quantum dot layer 720 may be located in the second central opening COP2. The second quantum dot layer 720 may overlap the second central area CA2. The second quantum dot layer 720 may fill the second central opening COP2. The second quantum dot layer 720 may overlap the second emission area EA2. The second sub-pixel PX2 may include the second organic light-emitting diode OLED2 and the second quantum dot layer 720.

The second quantum dot layer 720 may convert light of the first wavelength band generated by the emission layer 220 on the second pixel electrode 210G into light of a third wavelength band. For example, when light having a wavelength of 450 nm to 495 nm is generated by the emission layer 220 on the second pixel electrode 210G, the second quantum dot layer 720 may convert the light into light having a wavelength of 495 nm to 570 nm with a peak wavelength of 520 nm to 550 nm. Accordingly, in the second sub-pixel PX2, the light having a wavelength of 495 nm to 570 nm may be emitted to the outside through the upper substrate 400. According to some embodiments, the second quantum dot layer 720 may include second quantum dots QD2, a second scatterer SC2, and a second base resin BR2. The second quantum dots QD2 and the second scatterer SC2 may be dispersed in the second base resin BR2.

The transmissive layer 730 may be located in the third central opening COP3. The transmissive layer 730 may overlap the third central area CA3. The transmissive layer 730 may fill the third central opening COP3. The transmissive layer 730 may overlap the third emission area EA3. The third sub-pixel PX3 may include the third organic light-emitting diode OLED3 and the transmissive layer 730.

The transmissive layer 730 may emit light generated by the emission layer 220 on the third pixel electrode 210B to the outside without wavelength conversion. For example, when light having a wavelength of 450 nm to 495 nm is generated by the emission layer 220 on the third pixel electrode 210B, the transmissive layer 730 may emit the light to the outside without wavelength conversion. According to some embodiments, the transmissive layer 730 may include a third scatterer SC3 and a third base resin BR3. The third scatterer SC3 may be dispersed in the third base resin BR3. According to some embodiments, the transmissive layer 730 may not include quantum dots.

At least one of the first quantum dots QD1 or the second quantum dots QD2 may include an AIGS material. Quantum dots may have a size of several nanometers, and a wavelength of light after conversion may vary according to the size of quantum dots.

According to some embodiments, a core of a quantum dot may include an AIGS material. For example, the core of the quantum dot may include InxGa₍₁₋ₓ₎P, AgInxGa₍₁₋ₓ₎S₂, AgInS₂, AgGaS₂, CuInS₂, CuInSe₂, CuGaS₂, CuGaSe₂, ZnSe, ZnTexSe₍₁₋ₓ₎, or any combination thereof. Here, x may be a rational number in the range of greater than 0 and less than 1.

According to some embodiments, a quantum dot may have a core/shell structure in which one quantum dot surrounds another quantum dot. An interface between the core and the shell may have a concentration gradient in which a concentration of an element in the shell gradually decreases toward the center.

According to some embodiments, a quantum dot may have a core-shell structure including a core including a nanocrystal and a shell surrounding the core. The shell of the quantum dot may function as a protective layer for maintaining semiconductor characteristics by preventing chemical denaturation of the core and/or a charging layer for giving electrophoretic characteristics to the quantum dot. The shell may have a single or multi-layer structure. An interface between the core and the shell may have a concentration gradient in which a concentration of an element in the shell gradually decreases toward the center. Examples of the shell of the quantum dot may include an oxide of a metal or a non-metal, a semiconductor compound, and a combination thereof.

Examples of the oxide of the metal or the non-metal may include, but are not limited to, a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, or NiO and a ternary compound such as MgAl₂O₄, CoFe₂O₄, NiFe₂O₄, or CoMn₂O₄.

Examples of the semiconductor compound may include, but are not limited to, GsS, CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, and AlSb.

A quantum dot may have a full width at half maximum (FWHM) of an emission wavelength spectrum of about 45 nm or less, preferably about 40 nm or less, and more preferably about 30 nm or less. In this range, color purity or color reproducibility may be improved. Also, because light emitted through the quantum dot may be emitted in all directions, an optical viewing angle may be relatively improved.

Also, a quantum dot has a shape that is generally used in the art and is not specifically limited. More specifically, a quantum dot may have a spherical shape, a pyramidal shape, a multi-arm shape, a cubic nanoparticle shape, a nanotube shape, a nanowire shape, a nanofiber shape, or a nanoplate particle shape.

A color of light emitted from the quantum dot may be controlled according to a particle size, and thus, the quantum dot may have any of various emission colors such as blue, red, or green.

The first scatterer SC1, the second scatterer SC2, and the third scatterer SC3 may scatter light so that more light is emitted. The first scatterer SC1, the second scatterer SC2, and the third scatterer SC3 may increase light extraction efficiency. At least one of the first scatterer SC1, the second scatterer SC2, or the third scatterer SC3 may include a metal or a metal oxide for uniformly scattering light. For example, at least one of the first scatterer SC1, the second scatterer SC2, or the third scatterer SC3 may be at least one of TiO₂, ZrO₂, Al₂O₃, In₂O₃, ZnO, SnO₂, Sb₂O₃, or ITO. Also, at least one of the first scatterer SC1, the second scatterer SC2, or the third scatterer SC3 may have a refractive index of 1.5 or more. Accordingly, the light extraction efficiency of the functional layer 700 may be improved. In some embodiments, at least one of the first scatterer SC1, the second scatterer SC2, or the third scatterer SC3 may be omitted.

Each of the first base resin BR1, the second base resin BR2, and the third base resin BR3 may include a light transmitting material. For example, at least one of the first base resin BR1, the second base resin BR2, or the third base resin BR3 may include a polymer resin such as photocurable acryl, benzocyclobutene (BCB), or hexamethyldisiloxane (HMDSO).

The second capping layer CL2 may be located on the bank 600 and the functional layer 700. The second capping layer CL2 may protect the bank 600 and the functional layer 700. The second capping layer CL2 may prevent or reduce impurities such as external moisture and/or air from penetrating into and damaging the bank 600 and/or the functional layer 700. The second capping layer CL2 may include an inorganic material.

In the display apparatus 1 as described above, light of the second wavelength band may be emitted from the first sub-pixel PX1 to the outside, light of the third wavelength band may be emitted from the second sub-pixel PX2 to the outside, and light of the first wavelength band may be emitted from the third sub-pixel PX3 to the outside. That is, the display apparatus 1 may display a full-color image.

The filling layer 30 may be located between the light-emitting panel 10 and the color panel 20. According to some embodiments, the filling layer 30 may be located between the encapsulation layer 300 and the bank 600. The filling layer 30 may function as a buffer against external pressure, etc. The filling layer 30 may include a filler. According to some embodiments, the filling layer 30 may include a thermosetting or photocurable filler. The filler may be formed of an organic material such as methyl silicone, phenyl silicone, or polyimide. However, embodiments according to the present disclosure are not limited thereto, and the filler may include an organic sealant such as a urethane resin, an epoxy resin, or an acrylic resin, or an inorganic sealant such as silicone.

According to some embodiments, any one of the light-emitting panel 10 and the color panel 20 may include a column spacer 800. For example, according to some embodiments, the color panel 20 may include the column spacer 800. According to some embodiments, the light-emitting panel 10 may include the column spacer 800. According to some embodiments, the column spacer 800 may not be located between the light-emitting panel 10 and the color panel 20. In this case, only the filling layer 30 may be located between the light-emitting panel 10 and the color panel 20. The following will be described in detail assuming that the color panel 20 includes the column spacer 800. The column spacer 800 may be located on the bank 600 and may face the lower substrate 100. The column spacer 800 may cause the encapsulation layer 300 to be spaced apart from the bank 600. The column spacer 800 may pass through the filling layer 30. The column spacer 800 may include an organic material. According to some embodiments, the column spacer 800 may include an acrylic material.

The column spacer 800 may cause the light-emitting device and the functional layer 700 to be spaced apart from each other by a uniform interval. Accordingly, the filling layer 30 may be located in the display area DA with a uniform thickness. In other words, a distance between the first organic light-emitting diode OLED1 and the first quantum dot layer 710 may be substantially the same as a distance between the second organic light-emitting diode OLED2 and the second quantum dot layer 720. Also, a distance between the second organic light-emitting diode OLED2 and the second quantum dot layer 720 may be substantially the same as a distance between the third organic light-emitting diode OLED3 and the transmissive layer 730. When the column spacer 800 is omitted unlike in the present embodiments, a plurality of light-emitting devices and functional layers may not maintain a uniform interval. For example, a thickness of the filling layer 30 in the first central area CA1 may be different from a thickness of the filling layer 30 in the second central area CA2. In this case, a luminance of light emitted by the first organic light-emitting diode OLED1 and passing through the filling layer 30 overlapping the first central area CA1 may be different from a luminance of light emitted by the second organic light-emitting diode OLED2 and passing through the filling layer 30 overlapping the second central area CA2. According to some embodiments, the column spacer 800 may be arranged to pass through the filling layer 30, to cause the light-emitting device and the functional layer 700 to be spaced apart from each other by an interval (e.g., a uniform interval). Also, the filling layer 30 may prevent or reduce a phenomenon in which a luminance varies according to a location in the display area DA.

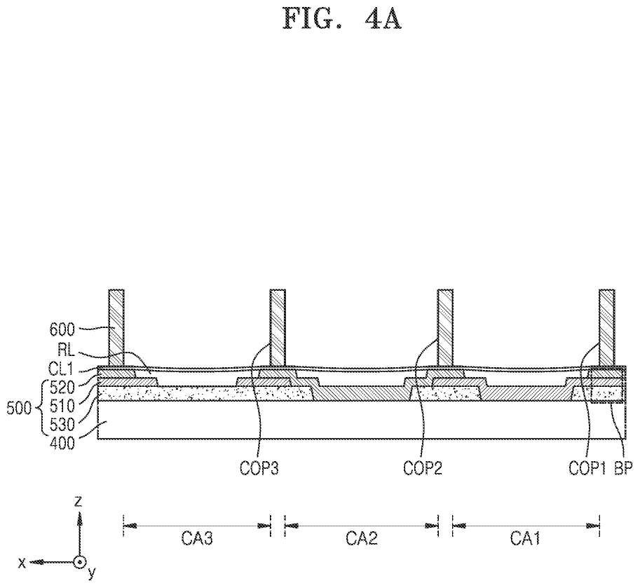

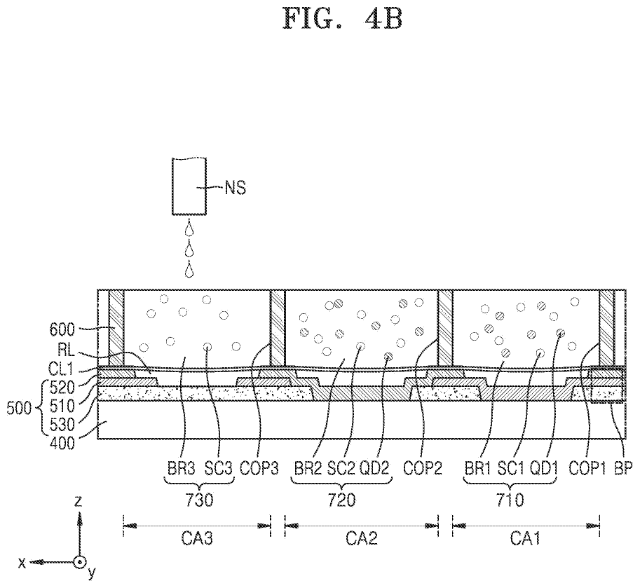

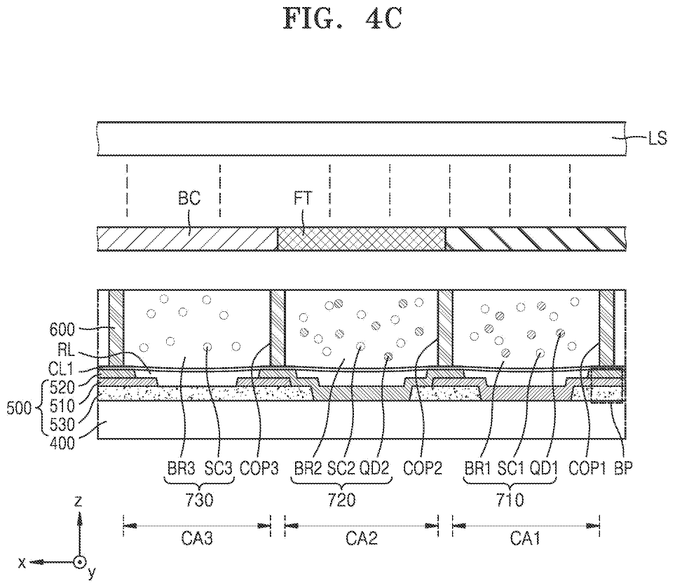

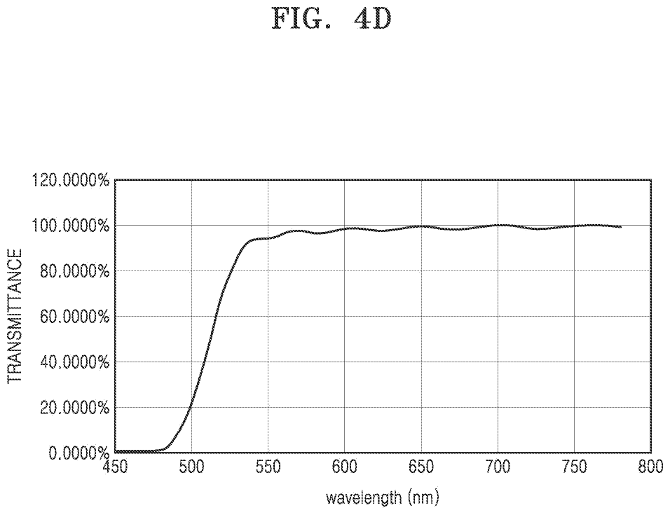

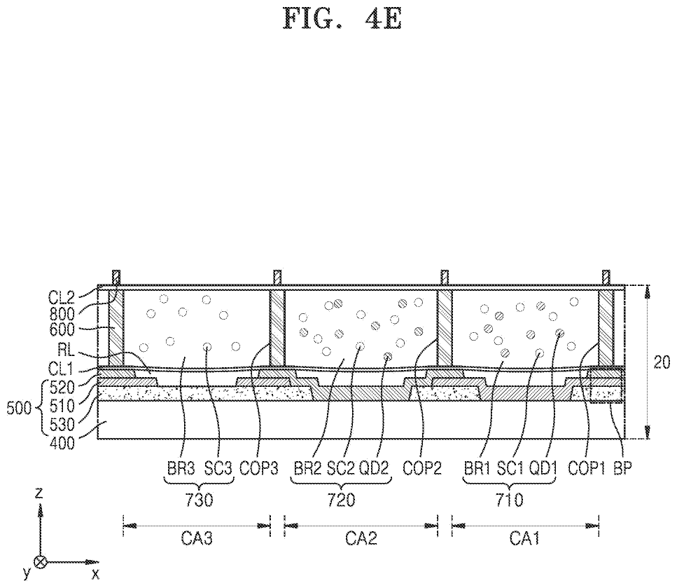

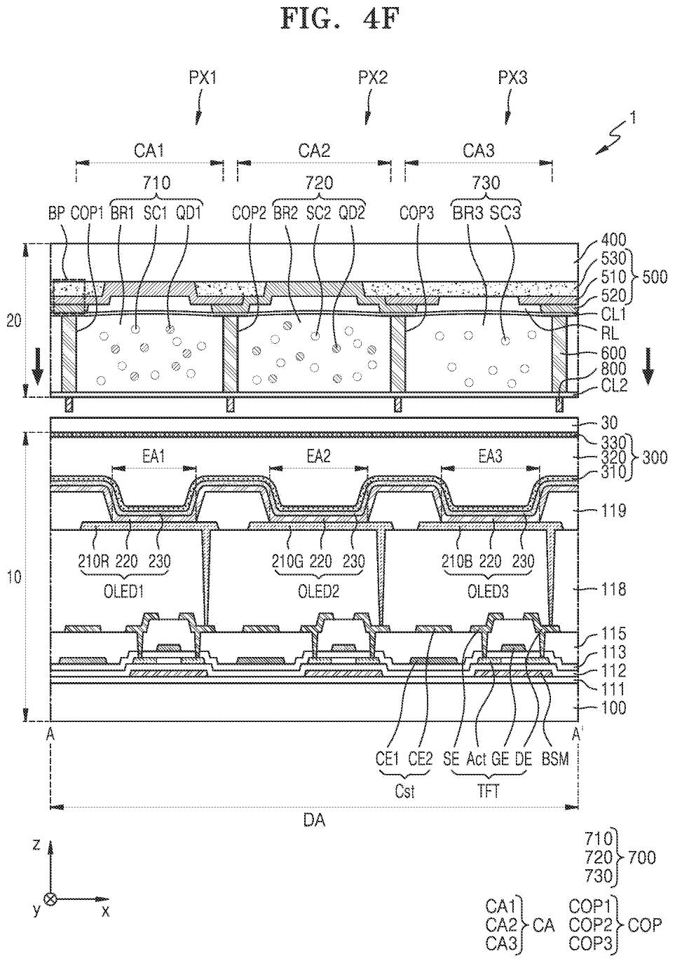

FIG. 4A is a cross-sectional view illustrating a method of manufacturing a color panel of FIG. 3.

Referring to FIG. 4A, the upper substrate 400 may be located in a chamber, and then the color filter layer 500 may be located on the upper substrate 400. In this case, the first color filter 510, the second color filter 520, and the third color filter 530 may be located on each area of the upper substrate 400, and on an area of the upper substrate 400, at least two of the first color filter 510, the second color filter 520, and the third color filter 530 may overlap each other.

After the color filter layer 500 is formed, the refractive layer RL may be located and then the first capping layer CL1 may be located on the refractive layer RL and the color filter layer 520. Next, the bank 600 may be located on the first capping layer CL1. The bank 600 may define the first central opening COP1, the second central opening COP2, and the third central opening COP3 corresponding to respective sub-pixels.

FIG. 4B is a cross-sectional view illustrating a method of manufacturing the color panel of FIG. 3.

Referring to FIG. 4B, a material for forming the first quantum dot layer 710, the second quantum dot layer 720, and the transmissive layer 730 may be supplied through a nozzle NS into the first central opening COP1, the second central opening COP2, and the third central opening COP3 by using an inkjet printing method, respectively. In this case, a plurality of nozzles NS may be provided to respectively correspond to the first central opening COP1, the second central opening COP2, and the third central opening COP3. In this case, the nozzles NS may respectively supply materials for forming the first quantum dot layer 710 and the second quantum dot layer 720 including quantum dots of different sizes into the first central opening COP1 and the second central opening COP2. Also, one of the plurality of nozzles NS may supply a material for forming the transmissive layer 730 including no quantum dots into the third central opening COP3.

After the first quantum dot layer 710, the second quantum dot layer 720, and the transmissive layer 730 are respectively located in the first central opening COP1, the second central opening COP2, and the third central opening COP3, the first quantum dot layer 710, the second quantum dot layer 720, and the transmissive layer 730 may be cured by irradiating ultraviolet rays (UV) having a wavelength of about 395 nm to the first quantum dot layer 710, the second quantum dot layer 720, and the transmissive layer 730 at atmospheric pressure (e.g., 1 atm) in a nitrogen (N₂) atmosphere in the chamber.

FIG. 4C is a cross-sectional view illustrating a method of manufacturing the color panel of FIG. 3. FIG. 4D is a graph illustrating a wavelength and an intensity of light passing through a filter of FIG. 4C.

Referring to FIGS. 4C and 4D, light may be irradiated by using a lamp LS onto the first quantum dot layer 710, the second quantum dot layer 720, and the transmissive layer 730 which are cured. In this case, the lamp LS may emit white light. Also, an intensity of light emitted by the lamp LS may be 5 lux or more and 40 lux or less. In this case, when an intensity of light emitted by the lamp LS is less than 5 lux, energy applied to the second quantum dot layer 720 may be too small. When an intensity of light emitted by the lamp LS exceeds 40 lux, energy applied to the second quantum dot layer 720 may be too large and may damage a material in the second quantum dot layer 720.

In this case, a blocking member BC and a filter FT may be located between the lamp LS and the first quantum dot layer 710, the second quantum dot layer 720, and the transmissive layer 730. For example, the blocking member BC may be located between the lamp LS and the first quantum dot layer 710 and between the lamp LS and the transmissive layer 730, and the filter FT may be located between the lamp LS and the second quantum dot layer 720. In this case, the blocking member BC may completely block light emitted by the lamp LS. The filter FT may transmit only light having a specific wavelength among light emitted by the lamp LS. For example, the filter FT may transmit most of light having a wavelength of about 520 nm or more as shown in FIG. 4D.

As described above, light passing through the filter FT may be provided only to the second quantum dot layer 720. In this case, the light may be irradiated to the second quantum dot layer 720 for a time ranging from 70 hours or more to 100 hours or less. For example, compared to a case where such light is not irradiated to the second quantum dot layer 720, when such light is irradiated to the second quantum dot layer 720 for 96 hours, a color reproduction rate may increase by about 0.6% from 125.0% to 125.6% in DCI-P3 evaluation and may increase by about 0.4% from 89.7% to 90.1% in BT2020 evaluation, and a color matching rate may increase by about 0.4% from 87.4% to 87.9% in BT2020 evaluation. Accordingly, it is found that a color matching rate and a color reproduction rate increase when light having a specific wavelength is applied for a certain time to the second quantum dot layer 720.

FIG. 4E is a cross-sectional view illustrating a method of manufacturing the color panel of FIG. 3.

Referring to FIG. 4E, after the first quantum dot layer 710, the second quantum dot layer 720, and the transmissive layer 730 are formed, the second capping layer CL2 may be formed through low-temperature chemical vapor deposition. Next, the color panel 20 may be manufactured through heat treatment. Next, the column spacer 800 may be located on the second capping layer CL2.

FIG. 4F is a cross-sectional view illustrating a method of manufacturing a display apparatus, according to some embodiments.

Referring to FIG. 4F, the manufactured color panel 20 may be attached to the light-emitting panel 10. In this case, the filling layer 30 may be located between the light-emitting panel 10 and the color panel 20. The filling layer 30 formed as a resin may be located on the color panel 20 or the light-emitting panel 10, and then the color panel 20 may be attached to the light-emitting panel 10.

In the display apparatus 1 manufactured as described above, color reproducibility of light passing through the second quantum dot layer 720 and a lifetime of the display apparatus 1 may be increased.

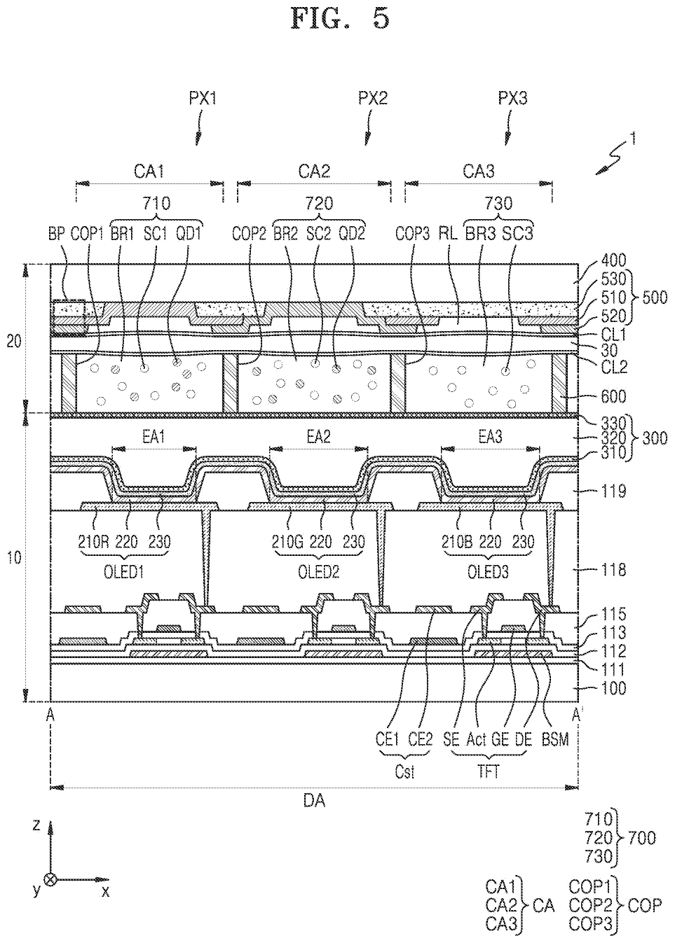

FIG. 5 is a cross-sectional view illustrating a display apparatus, according to some embodiments.

Referring to FIG. 5, the display apparatus 1 may include the light-emitting panel 10, the color panel 20, and the filling layer 30.

The light-emitting panel 10 may include the lower substrate 100 and a light-emitting device located on the lower substrate 100 and including the emission layer 220. The light-emitting device may be an organic light-emitting diode. According to some embodiments, the light-emitting panel 10 may include the first organic light-emitting diode OLED1, the second organic light-emitting diode OLED2, and the third organic light-emitting diode OLED3 located on the lower substrate 100. The first organic light-emitting diode OLED1, the second organic light-emitting diode OLED2, and the third organic light-emitting diode OLED3 may include the emission layer 220. The light-emitting panel 10 may include the lower substrate 100, the first buffer layer 111, the bias electrode BSM, the second buffer layer 112, the thin-film transistor TFT, the storage capacitor Cst, the gate insulating layer 113, the interlayer insulating layer 115, the planarization layer 118, the light-emitting device, and the encapsulation layer 300. The light-emitting device may include the first pixel electrode 210R, the second pixel electrode 210G, and the third pixel electrode 210B respectively located to correspond to the first organic light-emitting diode OLED1, the second organic light-emitting diode OLED2, and the third organic light-emitting diode OLED3, the emission layer 220, and the counter electrode 230. Also, the first organic light-emitting diode OLED1, the second organic light-emitting diode OLED2, and the third organic light-emitting diode OLED3 may respectively define the first emission area EA1, the second emission area EA2, and the third emission area EA3. The layers and elements of the light-emitting panel 10 are the same as or similar to those described above with reference to FIG. 3, and thus, a detailed description thereof will be omitted.

The color panel 20 may include the upper substrate 400, the color filter layer 500, the refractive layer RL, the first capping layer CL1, the second capping layer CL2, the bank 600, and the functional layer 700. In this case, the functional layer 700 may include the first quantum dot layer 710, the second quantum dot layer 720, and the transmissive layer 730. The upper substrate 400 may include the central area CA overlapping the light-emitting device. According to some embodiments, the central area CA may include the first central area CA1, the second central area CA2, and the third central area CA3. In this case, the color filter layer 500 may include the first color filter 510, the second color filter 520, and the third color filter 530 located in the first central area CA1, the second central area CA2, and the third central area CA3, respectively. In this case, the first color filter 510, the second color filter 520, and the third color filter 530 may overlap each other. The first color filter 510, the second color filter 520, and the third color filter 530 may overlap each other between any one of the central areas CA and another one of the central areas CA. The first color filter 510, the second color filter 520, and the third color filter 530 may overlap each other to constitute the light blocking unit BP. The first quantum dot layer 710 may fill the first central opening COP1, and may include the first quantum dots QD1, the first scatterer SC1, and the first base resin BR1. Also, the second quantum dot layer 720 may fill the second central opening COP2, and may include the second quantum dots QD2, the second scatterer SC2, and the second base resin BR2. The transmissive layer 730 may fill the third central opening COP3, and may include the third scatterer SC3 and the third base resin BR3. The color panel 20 is similar to that described with reference to FIG. 3, and thus, a detailed description thereof will be omitted. In this case, the filling layer 30 may be located between the first capping layer CL1 and the second capping layer CL2.

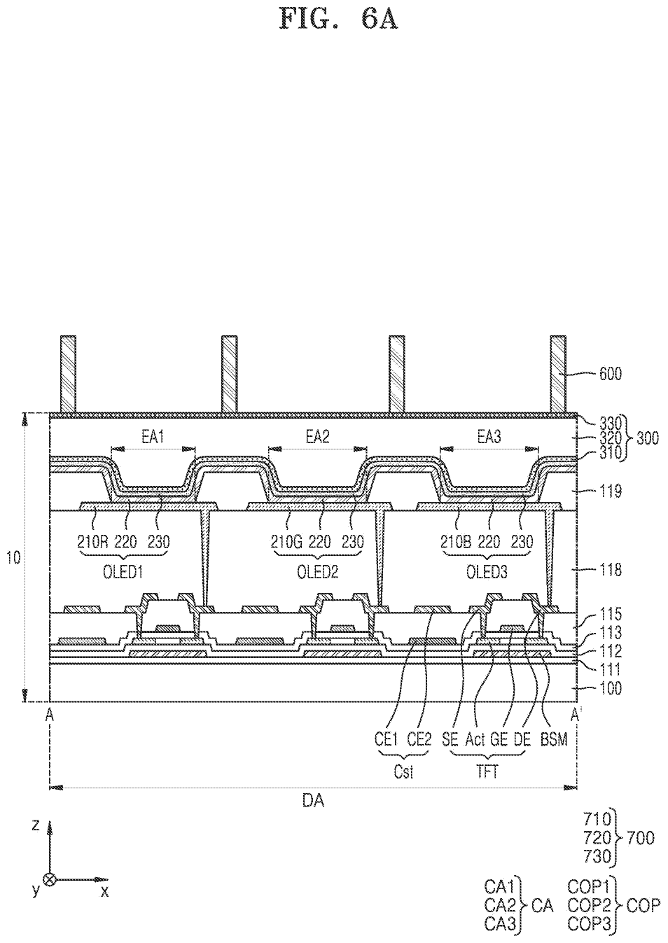

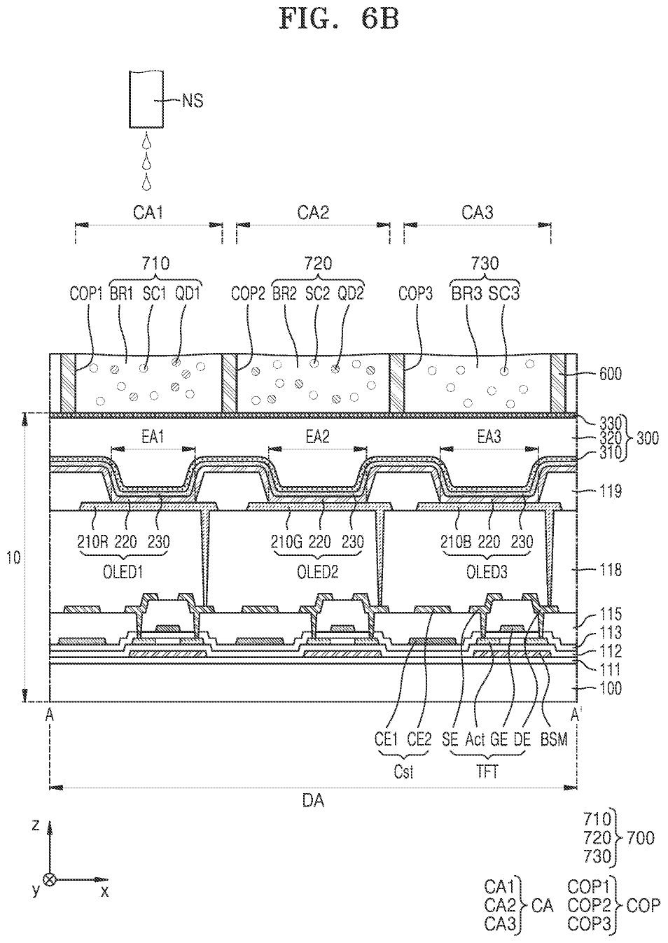

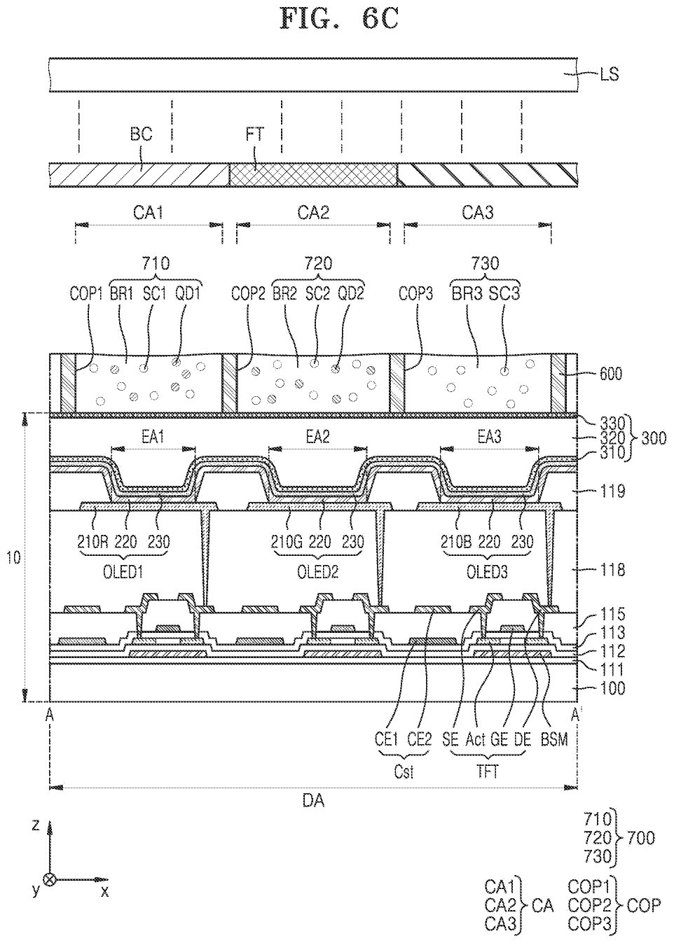

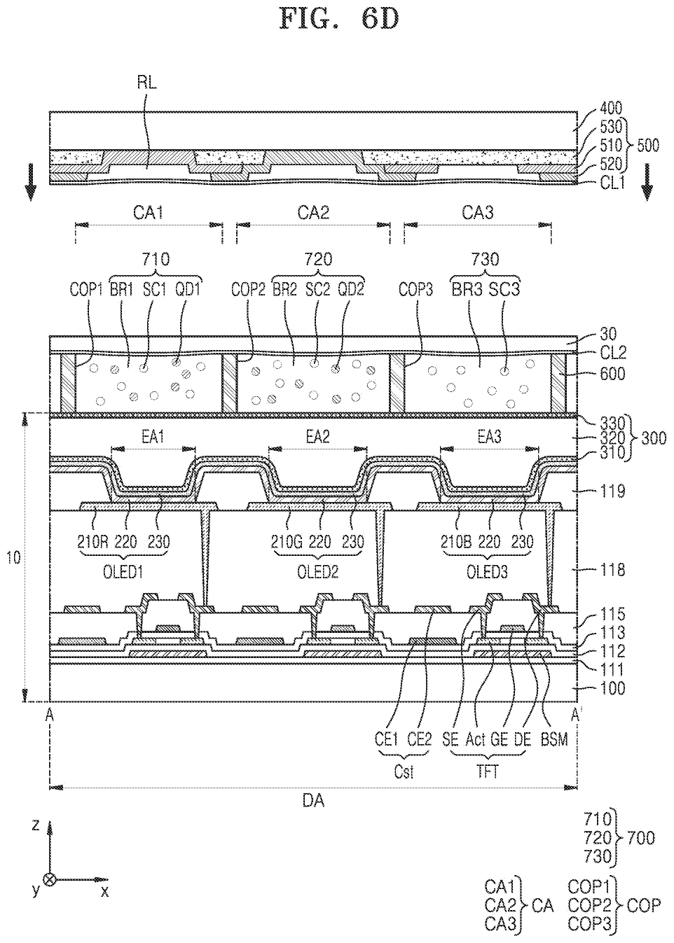

FIG. 6A is a cross-sectional view illustrating a method of manufacturing the display apparatus of FIG. 5.

Referring to FIG. 6A, the bank 600 may be located on the light-emitting panel 10. In this case, the bank 600 may include openings respectively corresponding to the first emission area EA1, the second emission area EA2, and the third emission area EA3.

FIG. 6B is a cross-sectional view illustrating a method of manufacturing the display apparatus of FIG. 5.

Referring to FIG. 6B, the first quantum dot layer 710, the second quantum dot layer 720, and the transmissive layer 730 may be respectively located in the first central opening COP1, the second central opening COP2, and the third central opening COP3 of the bank 600 through the nozzle NS by using an inkjet printing method. In this case, a plurality of nozzles NS may be provided to respectively correspond to the first central opening COP1, the second central opening COP2, and the third central opening COP3. Accordingly, the first quantum dot layer 710, the second quantum dot layer 720, and the transmissive layer 730 may be respectively located in the first central opening COP1, the second central opening COP2, and the third central opening COP3. Next, as described with reference to FIG. 4B, the first quantum dot layer 710, the second quantum dot layer 720, and the transmissive layer 730 may be cured.

FIG. 6C is a cross-sectional view illustrating a method of manufacturing the display apparatus of FIG. 5.

Referring to FIG. 6C, light may be emitted to the first quantum dot layer 710, the second quantum dot layer 720, and the transmissive layer 730 through the lamp LS. In this case, the lamp LS may emit white light, and the blocking member BC may block light traveling to the first quantum dot layer 710 and the transmissive layer 730. Also, the filter FT may transmit most of light having a specific wavelength or more among white light of the lamp LS. In this case, a time for which the lamp LS operates, an intensity of light emitted by the lamp LS, and a range of wavelengths of light passing through the filter FT are the same as those described with reference to FIG. 4C, and thus, a detailed description thereof will be omitted.

FIG. 6D is a cross-sectional view illustrating a method of manufacturing the display apparatus of FIG. 5.

Referring to FIG. 6D, the second capping layer CL2 may be located on the first quantum dot layer 710, the second quantum dot layer 720, and the transmissive layer 730 which are cured. Also, the filling layer 30 may be located on the second capping layer CL2. According to some embodiments, the filling layer 30 may not be located on the second capping layer CL2, but may be located on the second capping layer CL2 after being located on the first capping layer CL1. For convenience of explanation, the following will be described in detail assuming that the filling layer 30 is located on the second capping layer CL2.

The color filter layer 500 may be located on the upper substrate 400. The first color filter 510, the second color filter 520, and the third color filter 530 may be located to correspond to the first central area CA1, the second central area CA2, and the third central area CA3, respectively. In this case, the first color filter 510, the second color filter 520, and the third color filter 530 may overlap each other to constitute the light blocking unit BP. Also, the refractive layer RL may be located on the color filter layer 500, and then the first capping layer CL1 may be located on the refractive layer RL.

The upper substrate 400, the color filter layer 500, the refractive layer RL, and the first capping layer CL1 may be located on the filling layer 30, and the first capping layer CL1 may be fixed to the second capping layer CL2 by using the filling layer 30.

Accordingly, the efficiency of the display apparatus 1 may be improved, color reproducibility of light passing through the second quantum dot layer 720 may be improved, and a lifetime of the display apparatus 1 may be increased.

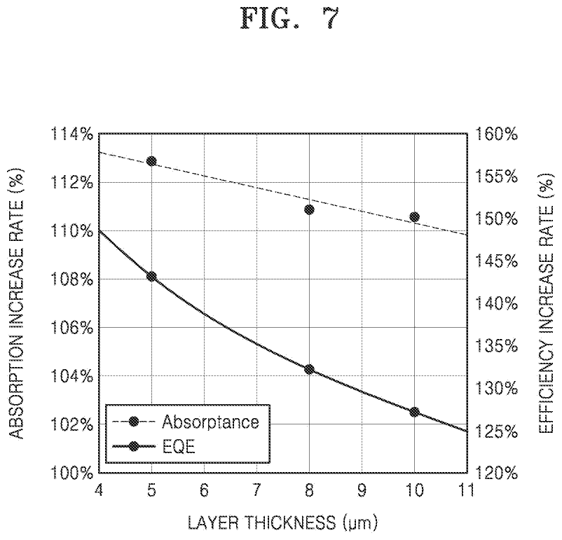

FIG. 7 is a graph illustrating an absorption increase rate and an efficiency increase rate between the display apparatus of FIG. 3 or 5 and an existing display apparatus.

Referring to FIG. 7, because the display apparatus 1 uses a quantum dot including an AIGS core, a light absorptance may be higher than that of an existing quantum dot. For example, a light absorptance of a core of a quantum dot may be at least 10% higher than that of InP core according to a thickness of a quantum dot. Accordingly, a display apparatus 1 including a quantum dot including an AIGS core may effectively absorb light. Also, because the display apparatus 1 uses a quantum dot including an AIGS core, efficiency may be improved. For example, the efficiency of a display apparatus 1 using a quantum dot including an AIGS core may be at least 20% higher than that of a display apparatus using a quantum dot including an InP core according to a thickness of a quantum dot.

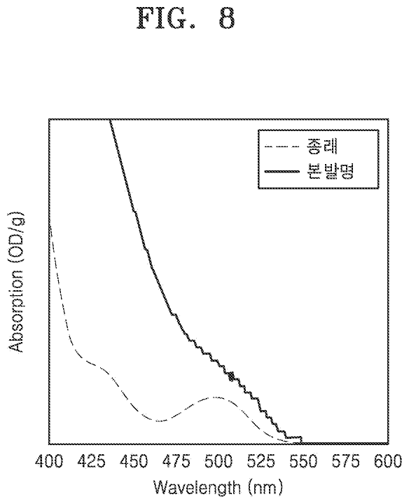

FIG. 8 is a graph illustrating an absorptance for each wavelength of a second quantum dot layer of FIG. 3 or 5.

Referring to FIG. 8, an absorptance for each wavelength of the second quantum dot layer may be higher than that of an existing second quantum dot layer including a quantum dot such as InP core. That is, when a second quantum dot layer includes a quantum dot having an AIGS core, an absorptance of light having a wavelength of 550 nm or less may be higher than that of an existing quantum dot layer.

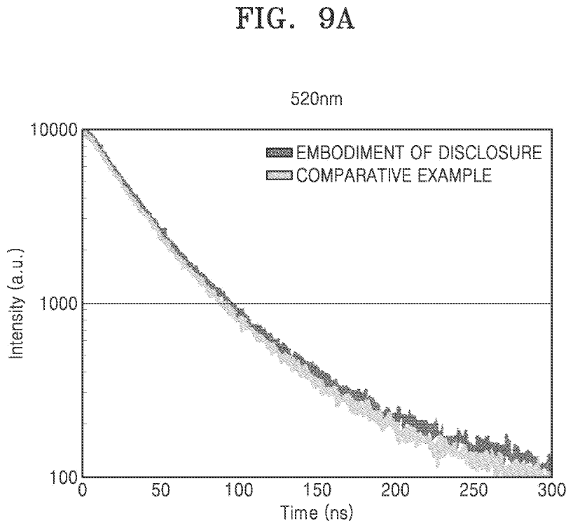

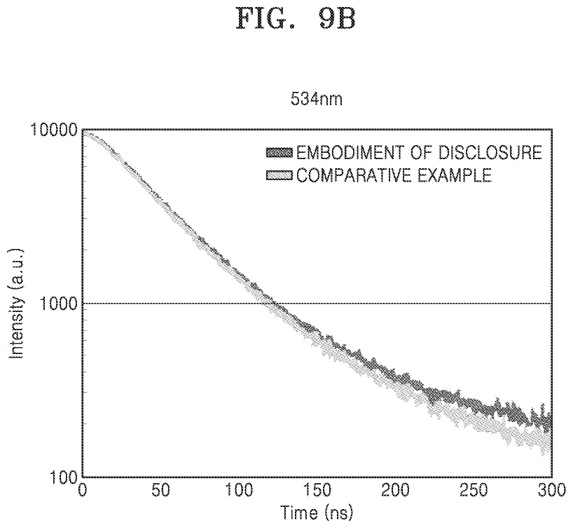

FIGS. 9A and 9B are graphs showing an intensity of light over time when light is irradiated to a second quantum dot layer.

Referring to FIGS. 9A and 9B, as described above, when light emitted by a lamp is transmitted through a filter and irradiated to a second quantum dot layer, a decay time of light of each wavelength may be longer than that when light is not irradiated.

In the above case, an experimental method may include irradiating a laser to a second quantum dot layer to excite electrons of a quantum dot and measuring light generated from the quantum dot outside the second quantum dot layer. In this case, the graphs of FIGS. 9A and 9B show a relative intensity (arbitrary unit) of light measured outside the second quantum dot layer over time. The laser may have a short wavelength of about 300 nm, and a wavelength of light generated from the quantum dot, passing through the second quantum dot layer, and then measured may be 520 nm and 534 nm.

It is found that assuming that a wavelength of light generated from the quantum dot and passing through the second quantum dot layer is 520 nm and 534 nm, a decay time of light of each wavelength when light is irradiated to the second quantum dot layer is longer than that when light is not irradiated.

Through the graphs of FIGS. 9A and 9B obtained through the above experiment, a tau of a decay time of light emitted from the second quantum dot layer including an AIGS quantum dot core may be calculated. In this case, the tau of the decay time of the light emitted from the second quantum dot layer may be calculated through a separate program by receiving data according to time and the measured relative intensity of light. In this case, the tau of the decay time of the light emitted from the second quantum dot layer refers to an average lifetime of the second quantum dot layer (e.g., an average lifetime of light emitted from the second quantum dot layer when light is irradiated to the second quantum dot layer).

In the above case, the tau of the decay time of the light emitted from the second quantum dot layer including the AIGS quantum dot core may be about 30 or more and 60 or less. Also, the tau of the decay time of the light emitted from the second quantum dot layer that includes the AIGS quantum dot core and to which light is irradiated may be about 45 or more and 80 or less.

A display apparatus according to some embodiments may improve a green color matching rate and improve energy efficiency.

According to a method of manufacturing a display apparatus according to some embodiments, a display apparatus having a relatively improved color matching rate and relatively improved energy efficiency may be manufactured.

The electronic or electric devices and/or any other relevant devices or components according to some embodiments of the present invention described herein may be implemented utilizing any suitable hardware, firmware (e.g. an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate. Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of the embodiments according to the present disclosure.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by one of ordinary skill in the art that various changes in form and details may be made therein without departing from the spirit and scope as defined by the following claims, and their equivalents.

What is claimed is:

1. A method of manufacturing a display apparatus, the method comprising:
locating a bank comprising a first central opening and a second central opening on an upper substrate;
locating a first quantum dot layer in the first central opening;
locating a second quantum dot layer in the second central opening; and
irradiating light having a wavelength of 520 nm or more to the second quantum dot layer.

2. The method of claim 1, further comprising:
locating a lamp to face the upper substrate; and
locating a filter between the lamp and the second quantum dot layer.

3. The method of claim 2, wherein the filter is configured to transmit the light having a wavelength of 520 nm or more.

4. The method of claim 2, wherein the lamp is configured to emit white light.

5. The method of claim 2, further comprising locating a blocking member between the lamp and the first quantum dot layer.

6. The method of claim 1, wherein an intensity of the light is in a range from 5 lux to 40 lux.

7. The method of claim 1, wherein the light is irradiated to the second quantum dot layer for a time in a range from 70 hours to 100 hours.

8. The method of claim 1, wherein the second quantum dot layer comprises a quantum dot comprising an AIGS core.

9. The method of claim 1, wherein the first quantum dot layer and the second quantum dot layer are respectively supplied into the first central opening and the second central opening by using an inkjet printing method.

10. The method of claim 1, further comprising locating a color filter layer between the upper substrate and the bank.

11. The method of claim 1, further comprising locating a capping layer on the first quantum dot layer and the second quantum dot layer.

12. A method of manufacturing a display apparatus, the method comprising:
locating a bank comprising a first central opening and a second central opening on a light-emitting panel;
locating a first quantum dot layer in the first central opening;
locating a second quantum dot layer in the second central opening; and
irradiating light having a wavelength of 520 nm or more to the second quantum dot layer.

13. The method of claim 12, further comprising:
locating a lamp to face the light-emitting panel; and
locating a filter between the lamp and the second quantum dot layer.

14. The method of claim 13, wherein the filter is configured to transmit the light having a wavelength of 520 nm or more.

15. The method of claim 13, wherein the lamp is configured to emit white light.

16. The method of claim 13, further comprising locating a blocking member between the lamp and the first quantum dot layer.

17. The method of claim 12, wherein an intensity of the light is in a range of 5 lux to 40 lux.

18. The method of claim 12, wherein the light is irradiated to the second quantum dot layer for a time in a range of 70 hours to 100 hours.

19. The method of claim 12, wherein the second quantum dot layer comprises a quantum dot comprising an AIGS core.

20. The method of claim 12, further comprising locating a capping layer on the first quantum dot layer and the second quantum dot layer.

21. A display apparatus comprising:
a display panel comprising sub-pixels; and
a color panel on the display panel and comprising quantum dot layers corresponding to the sub-pixels,
wherein a quantum dot layer from among the quantum dot layers comprises a quantum dot comprising an AIGS core,
wherein the AIGS core comprises at least one of InxGa₍₁₋ₓ₎P, AgInxGa₍₁₋ₓ₎S₂, AgInS₂, AgGaS₂, CuInS₂, CuInSe₂, CuGaS₂, CuGaSe₂, or ZnSe, ZnTexSe₍₁₋ₓ₎
(where x is a rational number greater than 0 and less than 1).

22. The display apparatus of claim 21, wherein light passing through a portion of the color panel where the quantum dot layer is located is green.

23. The display apparatus of claim 21, wherein a tau of a decay time of light passing through the quantum dot layer is in a range of 30 to 80.

24. The display apparatus of claim 21, further comprising a capping layer on the quantum dot layer.

25. The display apparatus of claim 21, further comprising a color filter corresponding to the quantum dot layer.
